(19) United States
(12) Patent Application Publication
(10) Pub. No.: US 2010/0199142 A1
(43) Pub. Date: Aug. 5, 2010

(54) ENCODING SCHEME, AND A DECODING SCHEME USING A SERIES OF LDPC CODES BASED ON FINITE INVERSIVE SPACES

(75) Inventors: Marcus Greferath, Co Dublin (IE); Cornelia Roessing, Co Dublin (IE); Mark Flanagan, Co Dublin (IE)

Correspondence Address: THE NATH LAW GROUP, 112 South West Street, Alexandria, VA, 22314, US

(73) Assignee: University College Dublin, National University of Ireland, Dublin (IE)

(21) Appl. No.: 12/451,388

(22) PCT Filed: Apr. 11, 2008
(86) PCT No.: PCT/EP2008/002889

§ 371 Date: Nov. 10, 2009

(30) Foreign Application Priority Data
Apr. 13, 2007 (IE) S2007/0271

(51) Int. Cl. H03M 13/09; G06F 11/10

(52) U.S. Cl. 714/752; 714/E11.032

(57) ABSTRACT

There is disclosed a method of creating an LDPC code that is defined by a parity-check matrix H. The parity-check matrix H is derived from a (0,1)-geometry which is induced by a finite inversive space. This inversive space has an order q where every circle in the inversive space contains exactly q+1 points, q is preferably even, and most preferably equal to 2. Where the inversive space has a dimension n. Where the (0,1)-geometry is formed as a derived geometric structure based on pencils of degree m≦n in the inversive space. The method includes construction of a binary K by N matrix H labelled by K circles and N pencils of the inversive space, wherein the (i, j)-entry of the matrix is 1 if circle i belongs to pencil j, and 0 otherwise. If the degree of the pencil is given by 2 then the parity-check matrix H needs to be transposed, i.e. H^{T} is used instead of H. A method of transmitting a message, a coder, a decoder and a data transmission system using such codes are also disclosed.

### BACKGROUND TO THE INVENTION

1. Field of the Invention

The present invention relates to an encoding scheme, and a corresponding decoding scheme using a series of LDPC codes each based on finite inversive spaces.

Noise in a digital communication system causes a fraction of bits that are transmitted or stored within the system to be received in error. Error-correcting codes are used in such systems to correct these errors. Recently, two classes of error-correcting codes have shown error-correcting performance close to that theoretically achievable, the so-called “Shannon limit”. These classes of error-correcting codes are known as turbo codes and low-density parity-check (LDPC) codes.

Turbo codes are a family of codes that use iterative decoding algorithms to achieve a level of performance close to the theoretical maximum. Turbo codes have low encoding and decoding complexity but suffer from a high decoding latency. This limits their usefulness for some high-data-rate communication systems and high-density magnetic storage systems.

LDPC codes have significantly lower decoding latency than turbo codes. However, most good LDPC codes are based on pseudo-random constructions meaning that implementations of such a code generally have a high level of complexity because of their inherent lack of structure. For this reason, structured LDPC codes are better suited to implementation in real-world communication and storage systems.

Every LDPC code is defined by a sparse parity-check matrix, commonly denoted H. The matrix H can be re-arranged by column permutations and Gauss-elimination so that H=[I_r|h], that is, so that H begins with an r by r identity matrix. (If H is singular, redundant rows are assumed to have first been removed until it is non-singular.) A message m, of length k=n−r can be encoded as x=m[h′|I_k)]′.

Every check matrix for an LDPC code has an associated graph called its “Tanner graph”. It has been proved that if this graph does not contain any cycles, then a very efficient decoding algorithm, based on message passing, can be used for the decoder. Cycles in the Tanner graph are associated with a reduction in the performance of this algorithm, but it has been observed that performance remains acceptable and often very good if the minimum cycle length in the underlying graph, this length being referred to as the “girth”, is sufficiently high. For this reason, it is desirable to design codes with check matrices whose associated Tanner graph is of high girth. Results of recent research suggest a further positive effect of large girth: there is a link between large girth and low error floor performance of the code. A low error floor means that the error correction performance of the code does not saturate at a “best attainable value” but continues to improve as the signal-to-noise ratio is increased.

Within the field of structured LDPC codes, there are several existing methodologies some of which are outlined below. One such methodology is to partition the parity-check matrix of the code into small circulant submatrices. This usually leads to a very low decoding complexity. Another methodology provides a variety of LDPC codes derived from geometrical structures. Among these, so-called “projective geometry codes” and “affine geometry codes” are known to perform well. Also, generalised quadrangles have been used in order to construct classes of LDPC codes.

As mentioned, the codes derived from partitioned parity-check matrices in a number of circulant submatrices have a decoder of very low complexity, but the resulting codes generally do not have a large girth or a low error-floor property. Finite geometry codes are suitable for very particular rates and do not allow any flexibility as to the channel model. Other geometrically induced code constructions tend to target girth only and are less optimal for ease of implementation.

2. Summary of the Prior Art

G. A. Margulis, “Explicit Constructions of Graphs without Short Cycles and Low Density Codes”, Combinatorica, volume 2, no. 1, p. 71-78, 1982 initiated the use of a Cayley graph of a group to construct a sparse bipartite graph which in turn induces an LDPC code once one writes down the incidence matrix of the graph. Further work in this direction has been done in J. Rosenthal and P. O. Vontobel, “Construction of regular and irregular LDPC codes using Ramanujan graphs and ideas from Margulis”, Proceedings of the 2001 IEEE International Symposium on Information Theory, p. 4, 2001 and J. D. Lafferty and D. N. Rockmore, “Codes and Iterative Decoding on Algebraic Expander Graphs”, Proceedings of the ISIT-A 2000, 2000. In both cases, Ramanujan graphs, which are optimal with respect to a certain expansion property, were constructed using the Cayley graph of a suitable group.

P. O. Vontobel and R. M. Tanner, “Construction of codes based on finite generalised quadrangles for iterative decoding”, Proc. International Symposium on Information Theory, Washington D.C., USA, p. 223, 2001 used finite generalised polygons, a geometrical concept, to design LDPC codes; this work targeted girth only and therefore is more complex than is desirable for practical implementation.

Y. Kou, S. Lin and M. P. C. Fossorier, “Low-density parity check codes based on finite geometries: A rediscovery and new results”, IEEE Transactions on Information Theory, vol. 47, no. 7, pp. 2711-2736, November 2001 designs LDPC codes based on the properties of finite Euclidean and projective geometries. An extension of the finite geometry codes of Kou to have a high-girth property is given in M. F. Flanagan, J. T. Craddock, C. P. Fewer and S. J. Redmond, “A Euclidean Geometry Based Algebraic Construction Technique for Girth-8 Gallager LDPC Codes”, IEEE Information Theory Workshop, ITW '06, Chengdu, China, 22-26 Oct. 2006. However, the codes of Flanagan have girth 8, and the ability to produce codes with grahes of greater girth would be preferred.

A very good overview of other existing constructions of structured LDPC codes with high girth is given in J. Moura, J. Lu and H. Zhang, “Structured Low-density parity-check codes”, IEEE Signal Processing Magazine, p. 42-55, January 2004. Moura also highlights the advantages of high-girth LDPC codes.

Also, J. Lu and J. M. F. Moura, “Structured LDPC codes for high-density recording: large girth and low error floor”, IEEE Transactions on Magnetics, vol. 42, issue 2, pp. 208-213, February 2006 introduces a ‘partition-and-shift’ design approach for structured LDPC codes which have good girth and minimum distance properties, and also are shown by simulation to have low error floors.

WO2007/030030, Yedidia et al., and JP2005065284, Fossorier et al., disclose aspects of LDPC codes derived from finite geometries. Yedidia discloses a method of extending achievable code parameters, therefore making the codes more suitable to a wider range of applications. Fossorier deals with a non-iterative decoding method for finite geometry-based LDPC codes.

U.S. Pat. No. 6,757,122, Kuznetsov et al., WO02/099976 Kurtas et al., and US2007/033497 Ba-Zhong et al.; describe a method whereby the parity-check matrix of the LDPC code is broken into submatrices which are small circulant matrices. This leads to low complexity in the decoder. However no girth or error floor advantage is shown for these codes.

### SUMMARY OF THE INVENTION

An aim of the present invention is to provide a range of LDPC codes, and a means for generating such codes, that have sufficient structure that their associated decoding algorithms are of an advantageously low complexity, while possessing, at the same time, large girth in the Tanner graph. A large number of codes that embody the present invention have check matrices whose Tanner graph is of girth 10 or more, and thus provide very good error correcting performance.

To this end, from a first aspect, this invention provides a method for encoding data using an LDPC code that is defined by a parity-check matrix H, where H is derived from a (0,1) geometry which is induced by a finite inversive space.

The inversive space used in any particular embodiment of the invention is characterised by two parameters: an order q, and a dimension n. Here 1+1 is the number of points on every circle in the inversive space. Preferably, q is even, since this ensures that the associated code has a girth in the Tanner graph of not less than 8. In the non-even case, it can be observed that the associated Tanner graph contains only few cycles of length 6. It has been found that particularly advantageous embodiments arise when q=2. Such embodiments have a girth in the Tanner graph of at least 10.

Given an inversive space of order q and dimension n, any particular embodiment of the invention uses a further object in such a space which is called a pencil. Pencils of inversive spaces are collections of circles that mutually touch each other in a given point. Depending on the inner structure of a pencil (that particularly determines the number of circles contained in it) the pencil is characterised by an additional parameter: the degree m≦n. Pencils of smaller degree have fewer circles than pencils with higher degree.

Embodiments of the invention may construct a binary K by N matrix H labelled by K circles and N pencils of the inversive space, wherein the (i, j)-entry of the matrix is 1 if circle i belongs to pencil j, and 0 otherwise. Exactly in case m=2 there holds K≧N, and then the parity-check matrix H is exchanged by its transpose H^{T}.

From a second aspect, this invention provides a method of encoding a message m comprising creating an LDPC code by a method according to the first aspect of the invention, and encoding the message m using the created code to obtain an encoded message x.

From a third aspect, the invention provides a method of transmitting a message m from a transmitter to a receiver comprising encoding the message m by a method according to the second aspect of the invention, transmitting the encoded message x over a transmission medium, decoding the encoded message x using two-phase message passing to recover the message m at the receiver.

For smaller pencil degree m (as compared to the dimension n of the inversive space), the invention can be used to particular advantage where the transmission medium includes a comparatively noisy, such as a wireless transmission medium. For higher pencil degree, it can be used to particular advantage where the transmission medium is less noisy, such as for magnetic storage media.

From a fourth aspect, the invention provides an encoder operative to select a message and encode it using an LDPC code created using the method embodying the first aspect of the invention.

From a fifth aspect, the invention provides a decoder operative to receive a code comprising an original message that has been encoded by an LDPC code created using the first aspect of the invention and to decode the code to recreate the original message. Such a decoder typically operates using a method of two-stage message passing.

From a sixth aspect, the invention provides a data transmission system for transmitting a message from a source to a receiver, comprising a coder according to the fourth aspect of the invention and a decoder according to the fifth aspect of the invention interconnected by a data transmission medium, the data transmission system being operative to transmit the message in accordance with the third aspect of the invention.

The present invention can provide codes having a range of lengths and rates that is sufficiently wide that to allow them to be useful in a range of applications extending to data communication (including inherently noisy applications, such as wireless communication) and data storage systems (including magnetic and optical disks, tapes). Also, embodiments of the invention are amenable to implementation because of the simplicity of the underlying geometric structure of the given inversive space.

### DESCRIPTION OF THE PREFERRED EMBODIMENT

An embodiment of the invention will now be described in detail, by way of example, with reference to the accompanying drawings, in which:

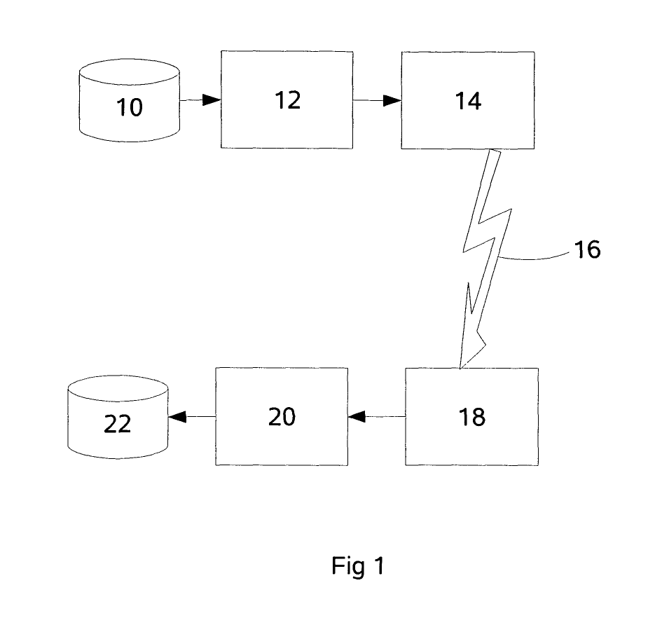

FIG. 1 is a block diagram of a data transmission system using a coder and a decoder embodying the invention.

As has been discussed, every LDPC code is characterised by the parity matrix H. Therefore, a specific LDPC code can be created by defining its parity-check matrix H and then using that matrix in a method of LDPC encoding.

Central to embodiments of the invention is the use of a geometric structure that is known as “inversive space” in the creation of a parity-check matrix H. Within such a space it is possible to identify a particular class of geometrical objects known as “pencils”, which are then used to derive a further incidence structure that is called a (0,1)-geometry. The incidence matrix of this geometry is a very sparse binary matrix that is used as the parity-check matrix H for a low-density parity-check (LDPC) code. Experimental evidence from simulations and preliminary theoretical studies suggest that the codes produced by such parity-check matrices have advantageous error-correction properties.

The underlying inversive space can be generated using, for example, algebraic tools provided in well-known computer algebra systems, including Magma and GaP.

The smallest inversive space is the inversive plane of order 2, which consists of 5 points and 10 circles. The construction process (and hence the implementation) for this inversive plane is illustrated below.

First, the incidence matrix for this plane is as follows:

$$( \begin{matrix} & & 0 & 1 & 2 & 3 & 4 & 5 & 6 & 7 & 8 & 9 \\ P 1 & \text{⋮} & 1 & 0 & 0 & 1 & 1 & 1 & 1 & 0 & 0 & 1 \\ P 2 & ⋮ & 0 & 1 & 1 & 0 & 1 & 1 & 1 & 0 & 1 & 0 \\ P 3 & ⋮ & 1 & 1 & 0 & 0 & 0 & 0 & 1 & 1 & 1 & 1 \\ P 4 & ⋮ & 0 & 1 & 1 & 1 & 0 & 1 & 0 & 1 & 0 & 1 \\ P 5 & ⋮ & 1 & 0 & 1 & 1 & 1 & 0 & 0 & 1 & 1 & 0\end{matrix} )$$

Here the rows are labelled by the points of the inversive plane (P1, . . . P5), and the columns by the circles (0, . . . ,9).

Two circles in this example are said to be tangent if their corresponding columns agree in exactly one entry. The labelling point of that entry will be called the “carrier”. For example, circles 0 and 1 are tangent to each other with carrier P3. A full set of circles being tangent to each other in one and the same point is called a “pencil”. The circles 0 and 1 form such a pencil. The carrier P3 carries further pencils, namely 6, 7 and 8, 9. After a brief check it can be verified that each point carries 3 pencils, and hence there are 15 pencils all in all.

A new binary matrix can therefore be obtained, labelled by the pencils that described above, and the circles that were given. This matrix has 15 rows and 10 columns, and there is a 1 in each position where the labelling circle is contained in the labelling pencil, and a 0 otherwise. This yields the following matrix:

$$M = ( \begin{matrix} & & 0 & 1 & 2 & 3 & 4 & 5 & 6 & 7 & 8 & 9 \\ P 11 & ⋮ & 1 & 0 & 0 & 0 & 0 & 1 & 0 & 0 & 0 & 0 \\ P 12 & ⋮ & 0 & 0 & 0 & 1 & 0 & 0 & 1 & 0 & 0 & 0 \\ P 13 & ⋮ & 0 & 0 & 0 & 0 & 1 & 0 & 0 & 0 & 0 & 1 \\ P 21 & ⋮ & 0 & 1 & 0 & 0 & 1 & 0 & 0 & 0 & 0 & 0 \\ P 22 & ⋮ & 0 & 0 & 1 & 0 & 0 & 0 & 1 & 0 & 0 & 0 \\ P 23 & ⋮ & 0 & 0 & 0 & 0 & 0 & 1 & 0 & 0 & 1 & 0 \\ P 31 & ⋮ & 0 & 0 & 0 & 0 & 0 & 0 & 0 & 0 & 1 & 1 \\ P 32 & ⋮ & 1 & 1 & 0 & 0 & 0 & 0 & 0 & 0 & 0 & 0 \\ P 33 & ⋮ & 0 & 0 & 0 & 0 & 0 & 0 & 1 & 1 & 0 & 0 \\ P 41 & ⋮ & 0 & 1 & 0 & 1 & 0 & 0 & 0 & 0 & 0 & 0 \\ P 42 & ⋮ & 0 & 0 & 1 & 0 & 0 & 0 & 0 & 0 & 0 & 1 \\ P 43 & ⋮ & 0 & 0 & 0 & 0 & 0 & 1 & 0 & 1 & 0 & 0 \\ P 51 & ⋮ & 1 & 0 & 1 & 0 & 0 & 0 & 0 & 0 & 0 & 0 \\ P 52 & ⋮ & 0 & 0 & 0 & 1 & 0 & 0 & 0 & 0 & 1 & 0 \\ P 53 & ⋮ & 0 & 0 & 0 & 0 & 1 & 0 & 0 & 1 & 0 & 0\end{matrix} )$$

The transpose of this matrix is then taken as the parity-check matrix of the LDPC code; that is, H=M^{T}.

As indicated earlier, this is a simple illustration, and the particular example sketched is only the shortest code within the constructed family, N=15. However the construction works for arbitrary dimensional inversive spaces and for pencils of all degrees, thus more important codes are those with significantly larger values of N.

In more detail: denote the so-called “order” of the underlying inversive space as q. This means that every circle contains exactly q+1 points. Then, vary the dimension of the inversive space, which will be represented by the number n. Finally, the size of the pencil involved will be associated with a number m called the “degree” of the pencil. For n and m as defined above, where m≦n, it will be found that the inversive space:
contains exactly qⁿ+1 points;
contains

$$K = {q}^{n - 1} \cdot \frac{{q}^{2 n} - 1}{{q}^{2} - 1}$$

circles, and
contains

$$N = ( {q}^{n} + 1 ) \cdot \frac{{q}^{n} - 1}{q - 1} \cdot {[ \begin{matrix}n - 1 \\ m - 1\end{matrix} ]}_{q}$$

pencils.

Here

$${[ \begin{matrix}n - 1 \\ m - 1\end{matrix} ]}_{q}$$

is the q-ary Gauss-Coefficient. Having this result, it is possible to construct a binary K by N matrix labelled by the circles (1 . . . K) and the pencils (1 . . . N). The (i, j)-entry of this matrix will be a 1 if circle i belongs to pencil j, and 0 otherwise. This definition yields a sparse binary matrix, which means that the vast majority of the entries of the matrix are 0. Each row of this matrix contains the same number of nonzero entries, and the same is true for each column. This property of the matrix means that the particular LDPC code checked by this matrix belongs to the class of regular codes. Finally, an initial choice of the order q of the inversive space to be even assures that the girth of the Tanner graph of this matrix is at least 8. A choice of q=2 assures that it is at least 10. In all other cases, the girth is at least 6. The larger girth in the even-order case has a positive impact on the performance of the proposed message passing decoder for the checked code.

As indicated, implementations of the invention can use a standard encoder for linear codes and a decoder that is also known as a “two-phase message passing” decoder, using new parity-check matrices defined as described above. Message passing or belief propagation is described in Pearl, J. (1988) “Probabilistic Reasoning in Intelligent Systems: Networks of Plausible Inference” (Revised Second Printing) San Francisco, Calif.: Morgan Kaufmann; and also in David J. C. MacKay, “Information Theory, Inference, and Learning Algorithms”, pp. 334-340. Cambridge: Cambridge University Press; and also in the Ph.D. thesis of Niclas. Wiberg, “Codes and Decoding on General Graphs” (1996), Linkoeping University, Sweden.

Some LDPC codes have a performance limitation known as an “error floor”. This is a region in which the error probability does not approach 0 as quickly at high signal-to-noise ratios (SNRs) as it does at low SNRs. For example, if error probability is plotted on a log scale against the SNR of a transmission channel, one definition of an error floor is that there is a region where the slope of the plotted curve approaches that of a horizontal line.

LDPC codes that embody the invention have been generated and their performance tested over the Additive white Gaussian noise (‘AWGN’) channel model. (AWGN is a standard communications channel), and preliminary simulations have not shown any error floor phenomenon in the range of SNRs for which tests were feasible.

LDPC codes provided by the invention can be used in a data transmission system, as will now be described. The data transmission system transmits data from a data source 10 to a destination 22. The data is encoded by a coder 12 that applies an LDPC code embodying the invention. The encoded data is received by a modulator 14 from which it is transmitted over a noisy data link 16. A demodulator 18 receives the encoded data, and possibly noise, from the link 16, and passes the received data to a decoder 20 embodying the invention. The decoded data, from which any noise has been removed, is then delivered from the decoder to the receiver 22.

Variations of the above described embodiments are possible, for example, it will be seen that matrices produced according to the above described embodiments can be further manipulated for example through column and/or row permutation prior to deployment as parity-check matrices in accordance with the present invention.

1-14. (canceled)

15. A computer-implemented method of creating an LDPC code comprising a binary K by N parity-check matrix H stored in a memory of a computing device, where H is derived from a (0,1)-geometry which is induced by a finite inversive space of order q, where q≧2 and where q is defined as every circle in the inversive space containing exactly q+1 points, and dimension n and where is H labelled by K circles and N pencils of the inversive space wherein pencils used for deriving the check matrix are of degree m, where m≦n, wherein the (i, j)-entry of the matrix is 1 if circle i belongs to pencil j, and 0 otherwise.

16. A method of creating an LDPC code according to claim 15 in which q is even.

17. A method according to claim 15 wherein for m=2, said parity-check matrix comprises HT.

18. A method of encoding a message m comprising creating an LDPC code by a method according to claim 15, and encoding the message m using the created code to create a coded message x.

19. A method of transmitting a message m from a transmitter to a receiver comprising encoding the message m by a method according to claim 18, transmitting the encoded message x over a transmission medium, decoding the encoded message x using two-phase message passing to recover the message m at the receiver.

20. A method of transmitting a message according to claim 19 in which the transmission medium includes a wireless transmission link.

21. An encoder operative to select a message and encode it using an LDPC code created in accordance with claim 15.

22. A decoder operative to receive a code comprising an original message that has been encoded an LDPC code created in accordance with claim 15 and to decode the code to recreate the original message.

23. A decoder according to claim 21 that operates using a method of two-stage message passing.

24. A data transmission system for transmitting a message from a source to a receiver comprising an encoder operative to select a message and encode it using an LDPC code created in accordance with claim 15 and a decoder operative to receive a code comprising an original message that has been encoded an LDPC code created in accordance with claim 15 and to decode the code to recreate the original message, said encoder and said decoder interconnected by a data transmission medium, the data transmission system being operative to transmit a coded message x created by encoding a message m comprising creating an LDPC code by a method according to claim 15.
